(19) United States
(12) Patent Application Publication
(10) Pub. No.: US 2026/0080134 A1
(43) Pub. Date: Mar. 19, 2026

(54) AUTOMATED WELLBORE ANALYSIS

(71) Applicant: Schlumberger Technology Corporation, Sugar Land, TX (US)

(72) Inventors: Vanessa da Silva Simoes, Houston, TX (US); Hiren Maniar, Houston, TX (US); Abhinav Kohar, Houston, TX (US); Valerian Guillot, Montpellier (FR); Ravi Chhibber, Houston, TX (US)

(21) Appl. No.: 19/324,957

(22) Filed: Sep. 10, 2025

Related U.S. Application Data
(60) Provisional application No. 63/694,314, filed on Sep. 13, 2024.

(51) Int. Cl. G06F 30/28; G01V 99/00; G06F 30/27

(52) U.S. Cl. CPC G06F 30/28; G01V 99/00; G06F 30/27

(57) ABSTRACT

A method for automating analysis of a plurality of wells includes receiving input data including a database related to the plurality of wells. The method also includes receiving a submission related to the plurality of wells at an autonomous agent. The method further includes performing an automated workflow for the analysis of one or more wells of the plurality of wells based on the submission using the autonomous agent. The method also includes generating an output to the submission based on the automated workflow using a writer agent of the autonomous agent. The method also includes displaying the output from the autonomous agent.

### CROSS-REFERENCE TO RELATED APPLICATIONS

This application claims priority to and the benefit of U.S. Provisional Ser. No. 63/694,314 filed on Sep. 13, 2024, the entirety of which is incorporated herein by reference to the extent consistent with the present disclosure.

### BACKGROUND

Geological software platforms are tools utilized in geoscience and petroleum engineering for interpreting subsurface data and modeling the earth's subsurface to enable analysis of complex datasets, such as those associated with wellbores. Wellbores in downhole wells present complex and varied geological surroundings, and wellbore log analysis typically involves multiple steps, including: data exploration, cleaning, correction, selection, model calibration, model evaluation, and information extraction, which are time-consuming, require substantial domain expertise, and risk introducing inconsistencies in final interpretations. Deploying machine learning in wellbore log applications is often hindered by challenges such as the complexity and diversity of subsurface conditions, the high costs of obtaining properly labeled training data, low-quality intervals and inconsistent data within input logs, and the frequent absence of one or more log types in each interval. Existing machine learning solutions for wellbore log analysis are generally task-specific and location-specific, requiring domain experts to invest significant effort in selecting, cleaning, and labeling logs, while incurring high computational costs to train individual models that are not transferable across tasks or geological settings. These limitations often reduce the efficiency and effectiveness that users may leverage geological software platforms for wellbore log interpretation.

What is needed, then, are systems and methods for automating wellbore analysis.

### SUMMARY

A method for automating analysis of a plurality of wells. The method includes receiving input data including a database related to the plurality of wells. The method also includes receiving a submission related to the plurality of wells at an autonomous agent. The method further includes performing an automated workflow for the analysis of one or more wells of the plurality of wells based on the submission using the autonomous agent. The method also includes generating an output to the submission based on the automated workflow using a writer agent of the autonomous agent. The method also includes displaying the output from the autonomous agent.

A computing system is also disclosed. The computing system includes one or more processors and a method system. The method system includes one or more non-transitory computer-readable media storing instructions that, when executed by at least one of the one or more processors, cause the computing system to perform operations for automating analysis of a plurality of wells. The operations include receiving input data including a database related to the plurality of wells. The operations also include receiving a submission related to the plurality of wells at an autonomous agent. The operations also include performing an automated workflow for the analysis of one or more wells of the plurality of wells based on the submission using the autonomous agent. The operations also include generating an output to the submission based on the automated workflow using a writer agent of the autonomous agent. The operations also include displaying the output from the autonomous agent.

A non-transitory computer-readable medium is also disclosed. The medium stores instructions that, when executed by one or more processors of a computing system, cause the computing system to perform operations for automating analysis of a plurality of wells. The operations include receiving input data including a database related to the plurality of wells. The operations also include receiving a submission related to the plurality of wells at an autonomous agent. The operations also include performing an automated workflow for the analysis of one or more wells of the plurality of wells based on the submission using the autonomous agent. The operations also include generating an output to the submission based on the automated workflow using a writer agent of the autonomous agent. The operations also include displaying the output from the autonomous agent.

It will be appreciated that this summary is intended merely to introduce some aspects of the present methods, systems, and media, which are more fully described and/or claimed below. Accordingly, this summary is not intended to be limiting.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIG. 1 illustrates an example of a system that includes various management components to manage various aspects of a geologic environment, according to an embodiment.

FIG. 2 illustrates an exemplary workflow of an autonomous agent for conducting automated wellbore analysis, according to an embodiment.

FIG. 3 illustrates a flowchart of a method for automated wellbore analysis, according to an embodiment.

FIG. 4 illustrates a flowchart of a method for automating analysis of a wellbore or a well or a plurality of wells, according to an embodiment.

FIG. 5 illustrates a schematic view of a computing system for performing at least a portion of the method(s) described herein, according to an embodiment.

### DETAILED DESCRIPTION

Reference will now be made in detail to embodiments, examples of which are illustrated in the accompanying drawings and figures. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, components, circuits, and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques, and workflows that are in accordance with some embodiments. Some operations in the processing procedures, methods, techniques, and workflows disclosed herein may be combined and/or the order of some operations may be changed.

### System Overview

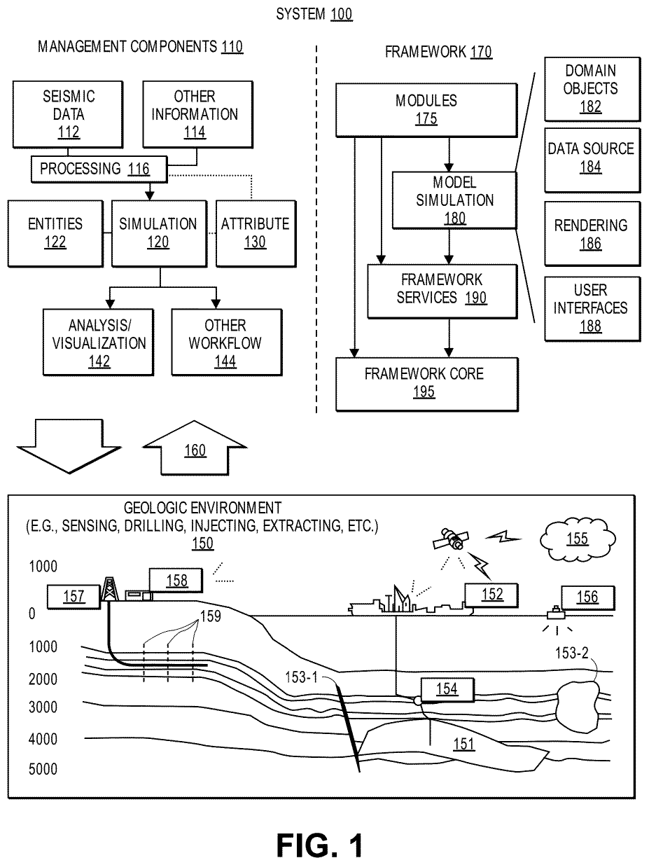

FIG. 1 illustrates an example of a system 100 that includes various management components 110 to manage various aspects of a geologic environment 150 (e.g., an environment that includes a sedimentary basin, a reservoir 151, one or more faults 153-1, one or more geobodies 153-2, etc.). For example, the management components 110 may allow for direct or indirect management of sensing, drilling, injecting, extracting, etc., with respect to the geologic environment 150. In turn, further information about the geologic environment 150 may become available as feedback 160 (e.g., optionally as input to one or more of the management components 110).

In the example of FIG. 1, the management components 110 include a seismic data component 112, an additional information component 114 (e.g., well/logging data), a processing component 116, a simulation component 120, an attribute component 130, an analysis/visualization component 142 and a workflow component 144. In operation, seismic data and other information provided per the components 112 and 114 may be input to the simulation component 120.

In an example embodiment, the simulation component 120 may rely on entities 122. Entities 122 may include earth entities or geological objects such as wells, surfaces, bodies, reservoirs, etc. In the system 100, the entities 122 may include virtual representations of actual physical entities that are reconstructed for purposes of simulation. The entities 122 may include entities based on data acquired via sensing, observation, etc. (e.g., the seismic data 112 and other information 114). An entity may be characterized by one or more properties (e.g., a geometrical pillar grid entity of an earth model may be characterized by a porosity property). Such properties may represent one or more measurements (e.g., acquired data), calculations, etc.

In an example embodiment, the simulation component 120 may operate in conjunction with a software framework such as an object-based framework. In such a framework, entities may include entities based on pre-defined classes to facilitate modeling and simulation. A commercially available example of an object-based framework is the MICROSOFT® .NET® framework (Redmond, Washington), which provides a set of extensible object classes. In the .NET® framework, an object class encapsulates a module of reusable code and associated data structures. Object classes may be used to instantiate object instances for use in by a program, script, etc. For example, borehole classes may define objects for representing boreholes based on well data.

In the example of FIG. 1, the simulation component 120 may process information to conform to one or more attributes specified by the attribute component 130, which may include a library of attributes. Such processing may occur prior to input to the simulation component 120 (e.g., consider the processing component 116). As an example, the simulation component 120 may perform operations on input information based on one or more attributes specified by the attribute component 130. In an example embodiment, the simulation component 120 may construct one or more models of the geologic environment 150, which may be relied on to simulate behavior of the geologic environment 150 (e.g., responsive to one or more acts, whether natural or artificial). In the example of FIG. 1, the analysis/visualization component 142 may allow for interaction with a model or model-based results (e.g., simulation results, etc.). As an example, output from the simulation component 120 may be input to one or more other workflows, as indicated by a workflow component 144.

As an example, the simulation component 120 may include one or more features of a simulator such as the ECLIPSE™ reservoir simulator (SLB, Houston Texas), the INTERSECT™ reservoir simulator (SLB, Houston Texas), etc. As an example, a simulation component, a simulator, etc. may include features to implement one or more meshless techniques (e.g., to solve one or more equations, etc.). As an example, a reservoir or reservoirs may be simulated with respect to one or more enhanced recovery techniques (e.g., consider a thermal process such as SAGD, etc.).

As an example, the simulation component 120 may include one or more features of a simulator such as SYMMETRY™ software (SLB, Houston, Texas). More particularly, SYMMETRY™ may process workflows in a single integrated environment with accurate thermodynamic fluid representation and consistent modeling across multiple disciplines including process, production, and HSE. The simulator integrates steady-state and transient (e.g., dynamic) analyses that may be tailored for each domain. This approach enables users to optimize processes in upstream, midstream, and downstream sectors while maximizing profits and minimizing capital expenditures. It may also help reduce emissions, energy consumption, and waste.

As an example, the simulation component 120 may include one or more features of a simulator such as PIPESIM™ (SLB, Houston, Texas). More particularly, PIPESIM™ is steady-state multiphase flow simulator that incorporates the three areas of flow modeling: multiphase flow, heat transfer and fluid behavior.

As an example, the simulation component 120 may include one or more features of a simulator such as OLGA™ (SLB, Houston, Texas). More particularly, OLGA™ is a dynamic multiphase flow simulator that models transient flow (e.g., time-dependent behaviors) to maximize production potential. Transient modeling is a component for feasibility studies and field development design. Dynamic simulation is useful in deep water and is used in both offshore and onshore developments to investigate transient behavior in pipelines and wellbores. Transient simulation with the OLGA™ simulator provides an added dimension to steady-state analysis by predicting system dynamics, such as time-varying changes in flow rates, fluid compositions, temperature, solids deposition, and operational changes.

In an example embodiment, the management components 110 may include features of a commercially available framework such as the PETREL® seismic to simulation software framework (SLB, Houston, Texas). The PETREL® framework provides components that allow for optimization of exploration and development operations. The PETREL® framework includes seismic to simulation software components that may output information for use in increasing reservoir performance, for example, by improving asset team productivity. Through use of such a framework, various professionals (e.g., geophysicists, geologists, and reservoir engineers) may develop collaborative workflows and integrate operations to streamline processes. Such a framework may be considered an application and may be considered a data-driven application (e.g., where data is input for purposes of modeling, simulating, etc.).

In an example embodiment, various aspects of the management components 110 may include add-ons or plug-ins that operate according to specifications of a framework environment. For example, a commercially available framework environment marketed as the OCEAN® framework environment (SLB, Houston, Texas) allows for integration of add-ons (or plug-ins) into a PETREL® framework workflow. The OCEAN® framework environment leverages. NET® tools (Microsoft Corporation, Redmond, Washington) and offers stable, user-friendly interfaces for efficient development. In an example embodiment, various components may be implemented as add-ons (or plug-ins) that conform to and operate according to specifications of a framework environment (e.g., according to application programming interface (API) specifications, etc.).

FIG. 1 also shows an example of a framework 170 that includes a model simulation layer 180 along with a framework services layer 190, a framework core layer 195 and a modules layer 175. The framework 170 may include the commercially available OCEAN® framework where the model simulation layer 180 is the commercially available PETREL® model-centric software package that hosts OCEAN® framework applications. In an example embodiment, the PETREL® software may be considered a data-driven application. The PETREL® software may include a framework for model building and visualization.

As an example, a framework may include features for implementing one or more mesh generation techniques. For example, a framework may include an input component for receipt of information from interpretation of seismic data, one or more attributes based at least in part on seismic data, log data, image data, etc. Such a framework may include a mesh generation component that processes input information, optionally in conjunction with other information, to generate a mesh.

In the example of FIG. 1, the model simulation layer 180 may provide domain objects 182, act as a data source 184, provide for rendering 186 and provide for various user interfaces 188. Rendering 186 may provide a graphical environment in which applications may display their data while the user interfaces 188 may provide a common look and feel for application user interface components.

As an example, the domain objects 182 may include entity objects, property objects and optionally other objects. Entity objects may be used to geometrically represent wells, surfaces, bodies, reservoirs, etc., while property objects may be used to provide property values as well as data versions and display parameters. For example, an entity object may represent a well where a property object provides log information as well as version information and display information (e.g., to display the well as part of a model).

In the example of FIG. 1, data may be stored in one or more data sources (or data stores, generally physical data storage devices), which may be at the same or different physical sites and accessible via one or more networks. The model simulation layer 180 may be configured to model projects. As such, a particular project may be stored where stored project information may include inputs, models, results and cases. Thus, upon completion of a modeling session, a user may store a project. At a later time, the project may be accessed and restored using the model simulation layer 180, which may recreate instances of the relevant domain objects.

In the example of FIG. 1, the geologic environment 150 may include layers (e.g., stratification) that include a reservoir 151 and one or more other features such as the fault 153-1, the geobody 153-2, etc. As an example, the geologic environment 150 may be outfitted with any of a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a well site and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or instead include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

As mentioned, the system 100 may be used to perform one or more workflows. A workflow may be a process that includes a number of worksteps. A workstep may operate on data, for example, to create new data, to update existing data, etc. As an example, a may operate on one or more inputs and create one or more results, for example, based on one or more algorithms. As an example, a system may include a workflow editor for creation, editing, executing, etc. of a workflow. In such an example, the workflow editor may provide for selection of one or more pre-defined worksteps, one or more customized worksteps, etc. As an example, a workflow may be a workflow implementable in the PETREL® software, for example, that operates on seismic data, seismic attribute(s), etc. As an example, a workflow may be a process implementable in the OCEAN® framework. As an example, a workflow may include one or more worksteps that access a module such as a plug-in (e.g., external executable code, etc.).

### Automated Wellbore Analysis

This disclosure generally relates to wellbore log analysis. The traditional methods for wellbore log analysis contain multiple steps including data exploration, data cleaning, data correction, data selection, model calibration, model evaluation and information extraction that is time consuming, requires domain expertise, and can bring inconsistencies in the final interpretation. Existing solutions for using machine learning in wellbore log analysis aim to solve one specific task for a particular location by building individual machine learning models for the specific tasks. Such procedures require substantial dedication by domain experts to select, clean, and label (interpret) the wellbore logs. A high-computational cost is incurred to train individual models, and they are not transferrable to other tasks or geologies.

The present disclosure provides systems and methods use an autonomous agent for an automatic artificial intelligence (AI) workflow for wellbore log analysis. In some implementations, the workflows for wellbore log analysis performs user defined tasks. Examples of tasks include formation evaluation, elastic properties prediction, identification of strong acoustic reflectors. The systems and methods help geoscientists achieve higher quality consistent interpretations. The systems and method use a foundation model that can provide direct inferences for multiple common tasks and is adaptable to multiple applications and formation types. The systems and methods use generative models to provide automation in an end-to-end wellbore analysis. The generative models automatically select work steps, automate iterations for data selection, propagate answers for the entire field evaluation, estimate uncertainties, and provide results assessment until a successful interpretation is achieved for the wellbore log analysis.

The present disclosure includes a number of practical applications that provide benefits and/or solve problems associated with wellbore log analysis. Examples of these applications and benefits are discussed in further detail below. One example benefit of the systems and methods of the present disclosure is an easy-to-use framework with improved automation consistency across multiple downstream applications, formation types, and improved data quality. Another example benefit of the systems and methods of the present disclosure is providing robustness in results. Another example benefit of the systems and methods of the present disclosure is adapting to the data, iterating through the work steps, and reviewing parts of data cleaning, data selection, and model training and inference until achieving quality inferences as well as providing the uncertainties. Another example benefit of the systems and methods of the present disclosure is providing high quality inference in new wells containing only basic information. Another example benefit of the systems and methods of the present disclosure is aiding users that are not data scientist experts with a petrophysical background achieve high quality results.

The systems and methods use an autonomous agent to automate a workflow for wellbore log analysis. An autonomous agent is an AI-powered software entity designed to operate independently within a specific domain of oil and gas operations. An autonomous agent can perceive its environment, make decisions, and take actions to achieve goals without constant human intervention. In some implementations, the autonomous agent is a machine learning model. In some implementations, the autonomous agent is a generative machine learning model.

The autonomous agent uses a multi-agent system with a plurality of autonomous agents in communication with each other. Each autonomous agent performs a different part of the wellbore log analysis workflow, and the outputs of each autonomous agents are provided as input to other autonomous agents. The plurality of autonomous agents receives the high-level task and data scope, and plan the execution of the task, perform iterations over the steps that include data quality control and data selection, machine learning training and inference, results evaluation, and information extraction until achieving the user-defined goal. The plurality of autonomous agents provides information, such as, the level of acceptable error for each objective versus the achieved error by the latest models, and the characteristics of zones with larger error to help the user.

The systems and methods ensure user privacy. In some implementations, the systems and methods use an autonomous agent that learns from new user interactions and examples, with the capability of adapting for best practices and new data along the interpretation. This dynamic model learns from expert knowledge for processing and interpreting wellbore logs and enables users to extrapolate this knowledge when interpreting new wells and fields without sharing the information outside of an organization.

In some implementations, the systems and methods use a foundation model that has been pre-trained and validated in multiple wells in different public datasets. The foundation model has the capability of handling inputs with different degrees of quality issues and can be adapted to multiple downstream tasks that have been developed and tested using multiple datasets. The foundation model focuses on quality, stability, and computational efficiency, as well as improving usability. The foundation model supports customizable workflows to provide end to end applications including but not limited to log quality control, formation evaluation, elastic properties prediction, reflection coefficient estimation, mineralogy estimation, and general log interpretation to enable the autonomous agent to consider a large amount of data in the interpretation.

One technical advantage of the systems and methods of the present disclosure is automating the wellbore log analysis workflow. The systems and methods aid rapid analysis of hundreds of scenarios. Another technical advantage of the systems and methods of the present disclosure is computational efficiency. Another technical advantage of the systems and methods of the present disclosure is improved quality of the data. The systems and methods automatically perform iterations to improve interpretation accuracy during the wellbore log information extraction.

One example use of the systems and methods of the present disclosure includes calculating formation evaluation in reservoir fields containing wells with large quantity of measured and interpreted logs, and wells with basic logs to help the petrophysicist to calculate porosity, saturation, organic content, pay zones, and permeability.

Another example use of the systems and methods of the present disclosure includes calculating acoustic velocities and elastic properties for the entire field to help the geomechanical expert.

Another example use of the systems and methods of the present disclosure includes helping the wellbore to seismic tie by identification of zones with strong acoustic reflection when either density or sonic are not measured or have a data quality issue. Another example use of the systems and methods of the present disclosure includes as part of the seismic to wellbore tie where strong acoustic reflectors need to be identified even when density or sonic are not present.

Another example use of the systems and methods of the present disclosure includes identification of minerals or patters of interest that are provided via examples. Another example use of the systems and method of the present disclosure includes receiving a new dataset and a geoscientist needs the formation evaluation performed for a large quantity of wells.

Another example use of the systems and method of the present disclosure includes accessing data and trying to evaluate a certain region for its reservoir properties for CO₂ injection projects. Another example use of the systems and method of the present disclosure includes as part of the geomechanical analysis predicting elastic properties in the entire field including wells where multiple logs can be missing.

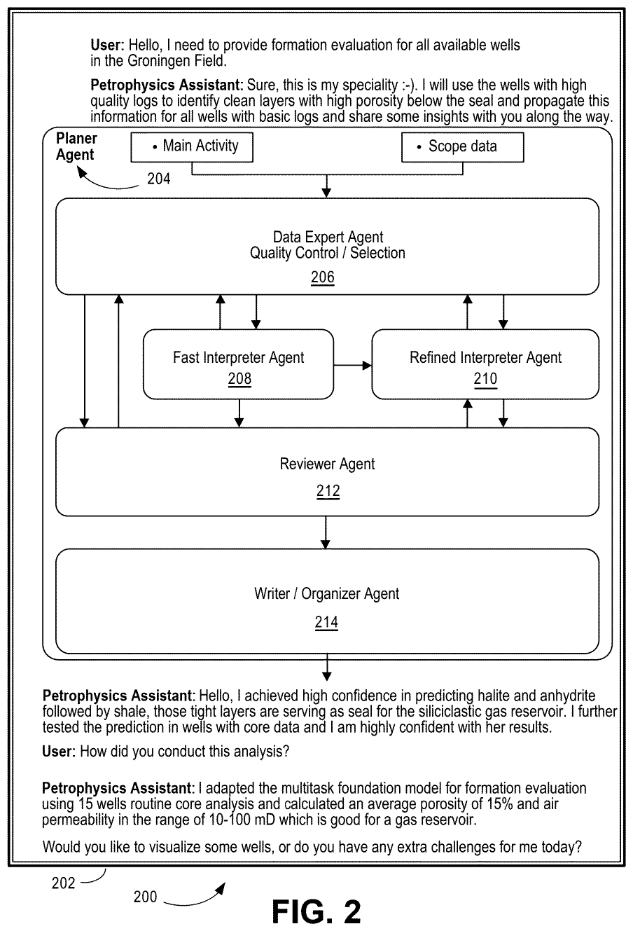

FIG. 2 illustrates an exemplary workflow or example environment 200 of an autonomous agent 202 for conducting automated wellbore analysis, according to an embodiment. The workflow 200 may be conducted on a geological software platform. One example of the geological software platform is PETREL™ by Schlumberger Information Solutions. Another example geological software platform is TECHLOG by Schlumberger Information Solutions. It should be appreciated that any geological software may be used with environment 200. The autonomous agent 202 automates a workflow for wellbore log analysis. In some implementations, the autonomous agent 202 is activated in response to the user accessing the autonomous agent 202.

A user accesses the autonomous agent 202 to perform wellbore log analysis using a client device of the user. In some implementations, the autonomous agent 202 is local to the client device of the user. In some implementations, the autonomous agent 202 is on a cloud server remote from the client device of the user accessed through a network. For example, the autonomous agent 202 is hosted on virtual machines in the cloud. For example, a uniform resource locator (URL) configured to an end point of the autonomous agent 202 is provided to the client device that the user may access using a browser on the client device through the network. The network may include one or multiple networks and may use one or more communication platforms and/or technologies suitable for transmitting data. The network may refer to any data link that enables transport of electronic data between devices of the environment 200. The network may refer to a hardwired network, a wireless network, or a combination of a hardwired network and a wireless network. In one or more implementations, the network includes the internet. The network may be configured to facilitate communication between the various computing devices via well-site information transfer standard markup language (WITSML) or similar protocol, or any other protocol or form of communication. Another example includes an application on the client device of the user provides access to the autonomous agent 202.

The user provides a submission and/or an input to the autonomous agent 202. In some implementations, the input is a query. In some implementations, the input is a complex data extraction request. In some implementations, the user opens a chat window within the autonomous agent 202 and provides the input to the autonomous agent 202. In some implementations, the input is a natural language textual input provided by the user.

The autonomous agent 202 uses a plurality of autonomous agents to perform the wellbore log analysis. In some implementations, each autonomous agent is a machine learning model. One example machine learning model is a large language model (LLM). Examples of the LLM is the Generative Pre-trained Transformer (GPT)-4 and Llama2. Another example machine learning model is a deep neural network (DNN). Another example machine learning model is a foundational model. In some implementations, the plurality of autonomous agents is arranged hierarchically where the output of one autonomous agent is provided as an input to another autonomous agent.

In some implementations, the autonomous agent 202 includes a planner agent 204. The planner agent 204 receives the input from the user and identifies activities in the input and a scope of the input. The planner agent 204 provides the identified activities and scope to a data expert agent. Example activities include queries about defining zones with potential for producing hydrocarbons, zones with risks of break out, zones with swelling shales. Examples of scope include data might be measured and interpreted logs and cores from multiple wells in a field.

In some implementations, the autonomous agent 202 includes a data expert agent 206 that performs quality control and data selection. The data expert agent 206 identifies wells that are used for training and validation of the data and data test sets. The data expert agent 206 uses the identified scope and activities of the user in identifying the wells that have data relevant to the identified scope and activities. For example, porosity and permeability and saturation are common tasks performed by users in formation evaluation in the mineralogy content and the data expert agent 206 identifies wells with data sensitive to porosity and saturation such as NMR and dielectric measurements, or permeability such as Stoneley wave velocity, as well as core laboratory measurements that can help to calibrate and validate the interpretation. The wells include diverse datasets. For example, exploratory wells, that are designed to test the subsurface geological properties, might belong in this category. The data expert agent 206 performs a quality control of the data from the selected wells to remove any errors that may have occurred in the data and ensure that the data is valid.

In some implementations, the autonomous agent 202 includes a fast interpreter agent 208. The fast interpreter agent 208 is a pretrained model that receives the data from the data agent. The fast interpreter agent 208 runs the data on the pretrained model. The fast interpreter agent 208 provides answers to the query using the pretrained model. For example, the fast interpreter agent 208 uses the pretrained model to answer a sheer velocity query from the user. The fast interpreter agent 208 provides the answer to a reviewer agent. Any answers the fast interpreter agent 208 is unable to provide using the pretrained model are sent to a refined interpreter agent 210.

In some implementations, the autonomous agent 202 includes a refined interpreter agent 210. The refined interpreter agent 210 uses the data that comes from the data expert agent for training and adapting a machine learning model. The refined interpreter agent 210 refines the data provided by the data expert (list of wells to use for training, validation, and test sets) and uses the refined data to train a machine learning model to answer the query. The refined interpreter agent 210 uses the datasets provided to adapt the model to predict new tasks or regions. The autonomous agent 202 provides the trained machine learning model to the reviewer agent 212 and/or the predicted answers of interest in the training data provided by the expert.

In some implementations, the autonomous agent 202 includes a reviewer agent 212. The reviewer agent 212 analyzes the results provided by the fast interpreter agent 208 and the trained machine learning model and the predicted results provided by the refined interpreter agent 210. The reviewer agent 212 analyzes the predicted results in the training, validation and test sets and identifies the quality of the trained machine learning models by the refined interpreter agent 210. The reviewer agent 212 evaluates the performance of the models (the trained machine learning model by the refined interpreter agent 210 or the trained machine learning model selected by the fast interpreter agent 208). In some implementations, the reviewer agent 212 identifies a percentage of error of the machine learning models. For example, after running the machine learning model the reviewer agent 212 identifies validation wells or intervals in the validation set that present large errors and evaluates if those errors are due to biases in the input logs, target logs or lack of examples in the training data. Or the reviewer agent 212 finds examples in the training set with similar characteristics that caused the model to provide the given prediction.

In some implementations, the reviewer agent 212 determines the performance of the machine learning model is below a metric or identifies an area of improvement for the machine learning model. For example, the reviewer agent 212 determines to remove one or more wells from the dataset and sends the output to the data export agent 206 to select new data for the query. Another example includes the reviewer agent 212 decides the machine learning model is performing poorly and provides the feedback to the refined interpreter agent 210 to retrain the machine learning model.

In some implementations, the reviewer agent 212 determines the performance of the machine learning model is above a threshold and sends the data to a writer/organizer agent 214. In some implementations, the reviewer agent 212 forwards a performance metric of the machine learning model with the data.

In some implementations, the autonomous agent 102 includes an organizer agent 214. The organizer agent 214 receives the metrics identified by the reviewer agent 212 and provides a response to the input of the user. In some implementations, the organizer agent 214 shares with the user the performance of the model in providing the output.

In some implementations, the response is a textual output. In some implementations, the response is a graph. In some implementations, the response is a diagram. In some implementations, the response is an image. In some implementations, the response is a video. For example, the response is displayed in the chat window on the device of the user. In some implementations, the response includes information from publicly available sources combined with predictions from proprietary machine learning models.

The plurality of autonomous agents performs multiple activities to provide the user with high quality interpretation associated with the user defined activity and scope of data in the input. The performance and generality of the plurality of autonomous agents can increase with the feedback and interaction between the autonomous agents. For example, improving quality indicators provided from the data expert agent 206 to improve the reviewer agent 212 decisions when finding errors, and improving the accuracy from the direct inference from the fast interpreter agent 208 after exposing the model to more tasks and regions.

The autonomous agent 202 uses a plurality of smart autonomous agents capable of taking decision based on intermediate feedback with the impact on final interpretation and an improvement of the final results. The autonomous agent 202 provides the user with more transparency of the reasoning when taking the decisions.

In some implementations, one or more computing devices (e.g., servers and/or devices) are used to perform the processing of the environments 200. The one or more computing devices may include, but are not limited to, server devices, cloud virtual machines, personal computers, a mobile device, such as, a mobile telephone, a smartphone, a PDA, a tablet, or a laptop, and/or a non-mobile device. The features and functionalities discussed herein in connection with the various systems may be implemented on one computing device or across multiple computing devices. Moreover, in some implementations, one or more subcomponent of the feature and functionalities discussed herein may be implemented are processed on different server devices of the same or different cloud computing networks.

In some implementations, each of the components of the environment 200 is in communication with each other using any suitable communication technologies. In addition, while the components of the environment 200 are shown to be separate, any of the components or subcomponents may be combined into fewer components, such as into a single component, or divided into more components as may serve a particular implementation. In some implementations, the components of the environment 200 include hardware, software, or both. For example, the components of the environment 200 may include one or more instructions stored on a computer-readable storage medium and executable by processors of one or more computing devices. When executed by the one or more processors, the computer-executable instructions of one or more computing devices can perform one or more methods described herein. In some implementations, the components of the environment 200 include hardware, such as a special purpose processing device to perform a certain function or group of functions. In some implementations, the components of the environment 100 include a combination of computer-executable instructions and hardware.

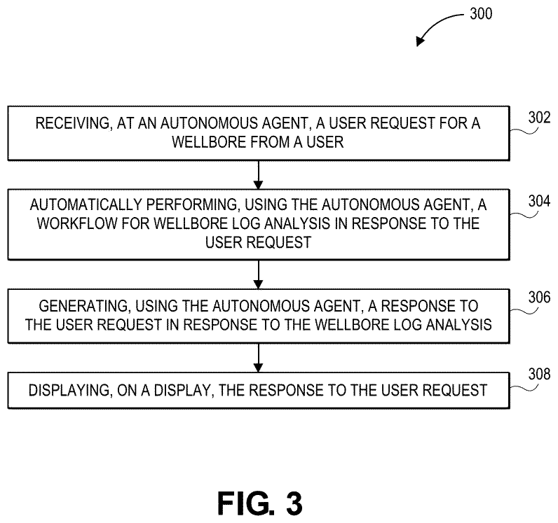

FIG. 3 illustrates an example method 300 for automated wellbore analysis. The actions the method 300 are discussed below in reference to the architecture of FIG. 2.

At 302, the method 300 includes receiving, at an autonomous agent, a user request for a wellbore from a user. In some implementations, the user request includes a user intent for a task or tasks (e.g., formation evaluation, elastic properties estimation, bad hole detection) and a data of interest (e.g. Basin A, field B, wells in a certain region, wells in a certain database). In some implementations, the user request includes a query. In some implementations, the user request is received in response to a user selecting from an interface (e.g., a drop-down list) a user intent and data of interest. In some implementations, the user request includes an activity and a scope of the data to use in responding to the user request. In some implementations, the user request is provided in a chat window on a device of the user and the response is displayed in the chat window.

At 304, the method 300 includes automatically performing, using the autonomous agent, a workflow for wellbore log analysis in response to the user request. In some implementations, the autonomous agent includes a plurality of autonomous agents, where each autonomous agent of the plurality of agents performs a portion of the wellbore log analysis. In some implementations, the plurality of autonomous agents are machine learning models. In some implementations, the plurality of autonomous agents is arranged in a hierarchy where an output of one autonomous agent is an input to another autonomous agent in the hierarchy.

In some implementations, the plurality of autonomous agents includes a planner agent that identifies an activity in the user request and a scope of data for responding to the user request. In some implementations, the plurality of autonomous agents includes a data expert agent that selects the data for responding to the user request and performs a quality control of the data. In some implementations, the plurality of autonomous agents includes a fast interpreter agent that uses pretrained machine learning models to provide answers to the user request. In some implementations, the plurality of autonomous agents includes a refined interpreter agent that trains a machine learning model to provide answers to the user request. In some implementations, the plurality of autonomous agents includes a reviewer agent that receives answers from a fast interpreter model and a refined interpreter model and verifies a quality of the answers. In some implementations, the plurality of autonomous agents includes an organizer agent that provides the output.

At 306, the method 300 includes generating, using the autonomous agent, a response to the user request in response to the wellbore log analysis.

At 308, the method 300 includes displaying, on a display, the response to the user request. In some implementations, the response includes natural language responding to the user request and a confidence level of the response. In some implementations, the response includes an explanation of an analysis performed by the autonomous agent in providing the response. In some implementations, the response includes a graph or visualization responding to the user request.

### Exemplary Method

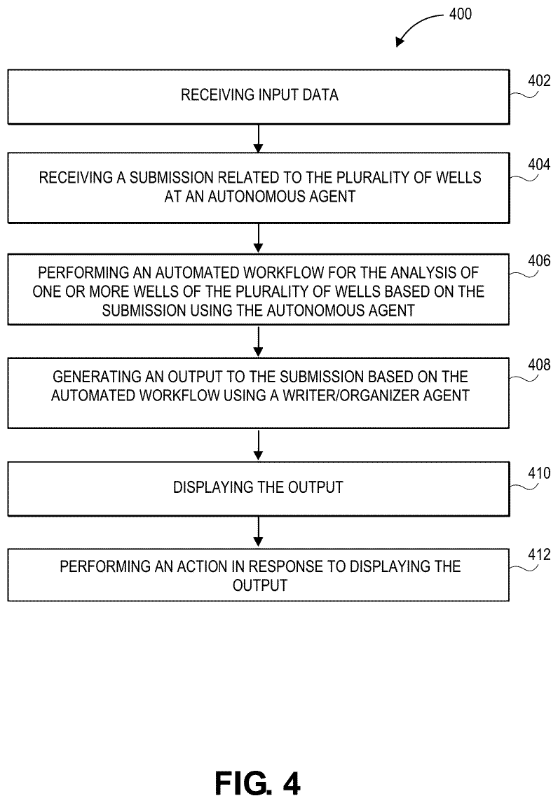

FIG. 4 illustrates a flowchart of a method 400 for automating analysis of a wellbore or a well of a plurality of wells, according to an embodiment. An illustrative order of the method 400 is provided below; however, one or more portions of the method 400 may be performed in a different order, simultaneously, repeated, or omitted. At least a portion of the method 400 may be performed using a computing system.

The method 400 may include receiving input data, as at 402. The input data may include a database for the plurality of wells. The database may include respective datasets for the plurality of wells. The database may include a respective dataset for each well of the plurality of wells. The respective dataset for each well of the plurality of wells may include wellbore data, measured log data, core data, derived data, interpreted data, seismic data, interpretations thereof, or the like, or a combination thereof.

The method 400 may also include receiving a submission related to the plurality of wells at an autonomous agent, as at 404. The submission may include a user query, a user request, or a combination thereof. The user query may include data of interest, region of interest, or a combination thereof. The user request may include a task, an activity, data scope for the task, a data scope for responding to the task, data scope for the activity, a data scope for responding to the activity, or the like, or a combination thereof.

The method 400 may further include performing an automated workflow for the analysis of one or more wells of the plurality of wells based on the submission using the autonomous agent, as at 406. The autonomous agent may include one or more machine learning (ML) models. The one or more ML models may be or include one or more pre-trained ML models. Any one or more ML models and/or any one or more of the pre-trained ML models thereof may include, be operated by, or be operated based on a respective configuration file. The respective configuration file may define one or more parameters for operating each of the one or more ML models or the one or more pre-trained ML models thereof. The respective configuration file may be in a JavaScript Object Notation (JSON) format.

The one or more parameters of the configuration file may define one or more of the following: one or more pre-trained models to be utilized, one or more log types to be utilized as input, a target data of interest for one or more of the steps of the workflow, a type of data augmentation and/or intensity of one or more alterations to be utilized, a loss to be minimized when optimizing the model (e.g., pre-trained model, fine-tuned model, combination thereof, etc.), one or more regularizers to be added to the loss (e.g., physics based equations, etc.), a maximum and/or minimum number of epochs to run the model, a number of free layers for fine-tuning the pre-trained model, one or more post-processing workflows to be performed to the output logs to follow one or more physical constraints, a number of times the model will perform or run the same interval when estimating one or more uncertainties, or any combination thereof. The configuration file may be altered based on, as least in part, the data and/or one or more steps taken by an agent, user, and/or domain expert. For example, the configuration file (e.g., JSON) may be altered based on, at least in part, a size and/or quality of the data and/or the one or more steps. The configuration file may be adapted or modified by the refined interpreter 210 when creating the samples, during fine-tuning, when evaluating results to improve the results, or the like, or any combination thereof.

In at least one embodiment, performing the automated workflow 406 may include identifying the user query, the user request, or a combination thereof of the submission using a planner agent 204 to provide an identified user query, an identified user request, or a combination thereof, respectively.

In at least one embodiment, performing the automated workflow 406 may include selecting a first dataset of the database using a data expert agent 206 and based on the submission. The data expert agent 206 may select the first dataset based on the identified user query, the identified user request, or a combination thereof.

In at least one embodiment, performing the automated workflow 406 may include performing a quality control workflow on the first respective dataset using the data expert agent 206 and based on the submission, the input data, or a combination thereof. The data expert agent 206 may perform the quality control workflow on the first dataset based on the submission using the data expert agent 206, one or more of the ML models, or a combination thereof.

In at least one embodiment, performing the automated workflow 406 may include generating a first set of predictions using a fast interpreter agent 208 and based on the one or more machine learning (ML) models, the first dataset, the submission, or a combination thereof. The first set of predictions may be generated based on the one or more ML models. The first set of predictions may be generated based on the submission. The first set of predictions may be generated based on the submission and the one or more ML models.

In at least one embodiment, performing the automated workflow 406 may include selecting a second dataset of the database using the data expert agent 206 and based on the first set of predictions from the fast interpreter agent 208 and the input data.

In at least one embodiment, performing the automated workflow 406 may include generating a second set of predictions using the fast interpreter agent 208 and based on the second dataset, the submission, the one or more ML models, or a combination thereof.

In at least one embodiment, performing the automated workflow 406 may include fine-tuning at least one ML model of the one or more ML models using a refined interpreter agent 210 to provide at least one fine-tuned ML model. The refined interpreter agent 210 may fine-tune at least one ML model based on the first set of predictions from the fast interpreter agent 208, the second set of predictions from the fast interpreter agent 208, the input data, the submission, or a combination thereof. Fine-tuning the at least one ML model may include modifying the respective configuration file of the at least one ML model to produce a modified configuration file using the refined interpreter agent 210. Fine-tuning the at least one ML model may include modifying the one or more parameters of the respective configuration file of the at least one ML model based on the first set of predictions from the fast interpreter agent 208, the second set of predictions from the fast interpreter agent 208, the input data, the submission, or a combination thereof.

In at least one embodiment, performing the automated workflow 406 may include verifying a quality of the first set of predictions and/or the second set of predictions using a reviewer agent 212 based on the input data, the one or more ML models, the one or more fine-tuned ML models, or a combination thereof. Verifying the quality may include performing an error analysis of the first set of predictions and/or the second set of predictions based on the input data, the one or more ML models, the one or more fine-tuned ML models, or a combination thereof. Verifying the quality may include further fine-tuning the at least one fine-tuned ML model based on the error analysis. Further fine-turning the at least one fine-tuned ML model may include modifying the modified configuration file based on the error analysis.

In at least one embodiment, the automated workflow 406 or one or more portions thereof may be iterative. For example, the automated workflow 406, which may be represented by the architecture of FIG. 2, or one or more portions thereof may be iterative. For example, as illustrated in FIG. 2, the fast interpreter agent 208 may be capable of or configured to direct an output to the data expert agent 206 and receive an output therefrom, the process of which may be iterative. In another example, the refined interpreter agent 210 may be capable of or configured to direct an output to the data expert agent 206 and receive an output therefrom, the process of which may be iterative. In yet another example, the refined interpreter agent 210 may be capable of or configured to fine-tune any one or more of the ML models in an iterative process.

The method 400 may further include generating an output to the submission based on the automated workflow using a writer/organizer agent, as at 408. The output may be based on the first set of predictions, the second set of predictions, or a combination thereof. The output may include a response based on the first set of predictions, the second set of predictions, or a combination thereof. The response may include a natural language response to the submission. The response may include an explanation of an analysis performed by the autonomous agent. The response may include a confidence level of the response. The response may include a visualization, a graph, or a combination thereof.

The method 400 may further include displaying the output, as at 410. The method 400 may also include performing an action in response to displaying the output, as at 412. The action may include generating or transmitting a signal that recommends, instructs, or causes a physical action to occur. The physical action may include one or more of optimizing a trajectory of a wellbore drilling operation, conducting drilling operations, conducting an exploratory operation, utilizing the single-upscaled permeability model in a simulation model, designing a production strategy, designing a hydraulic fracturing strategy, conducting risk assessments, or any combination thereof.

### Exemplary Computing System

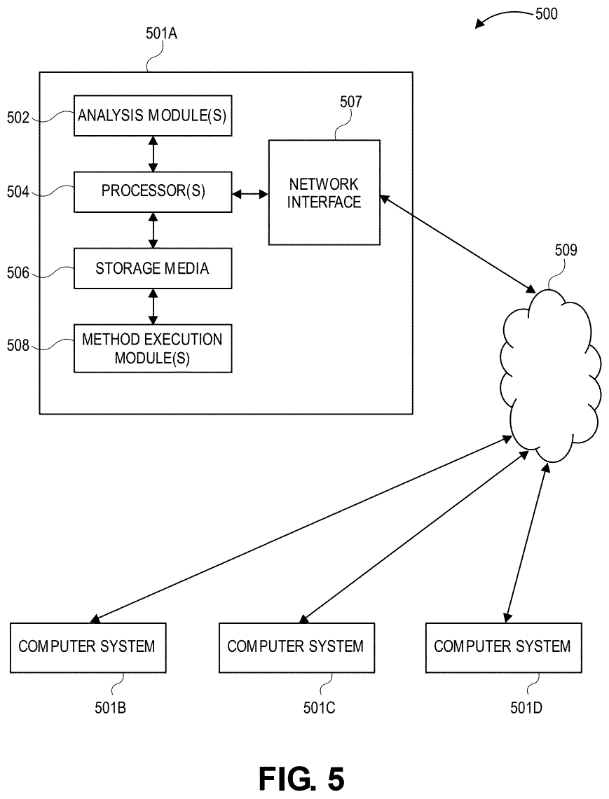

In some embodiments, the methods of the present disclosure may be executed by a computing system. FIG. 5 illustrates an example of such a computing system 500, in accordance with some embodiments. The computing system 500 may include a computer or computer system 501A, which may be an individual computer system 501A or an arrangement of distributed computer systems. The computer system 501A includes one or more analysis modules 502 that are configured to perform various tasks according to some embodiments, such as one or more methods disclosed herein. To perform these various tasks, the analysis module 502 executes independently, or in coordination with, one or more processors 504, which is (or are) connected to one or more storage media 506. The processor(s) 504 is (or are) also connected to a network interface 507 to allow the computer system 501A to communicate over a data network 509 with one or more additional computer systems and/or computing systems, such as 501B, 501C, and/or 501D (note that computer systems 501B, 501C and/or 501D may or may not share the same architecture as computer system 501A, and may be located in different physical locations, e.g., computer systems 501A and 501B may be located in a processing facility, while in communication with one or more computer systems such as 501C and/or 501D that are located in one or more data centers, and/or located in varying countries on different continents).

A processor may include a microprocessor, microcontroller, processor module or subsystem, programmable integrated circuit, programmable gate array, or another control or computing device.

The storage media 506 may be implemented as one or more computer-readable or machine-readable storage media. Note that while in the example embodiment of FIG. 5 storage media 506 is depicted as within computer system 501A, in some embodiments, storage media 506 may be distributed within and/or across multiple internal and/or external enclosures of computing system 501A and/or additional computing systems. Storage media 506 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above may be provided on one computer-readable or machine-readable storage medium, or may be provided on multiple computer-readable or machine-readable storage media distributed in a large system having possibly plural nodes. Such computer-readable or machine-readable storage medium or media is (are) considered to be part of an article (or article of manufacture). An article or article of manufacture may refer to any manufactured single component or multiple components. The storage medium or media may be located either in the machine running the machine-readable instructions, or located at a remote site from which machine-readable instructions may be downloaded over a network for execution.

In some embodiments, computing system 500 contains one or more method execution module(s) 508. In the example of computing system 500, computer system 501A includes the method execution module 508. In some embodiments, a single method execution module may be used to perform some aspects of one or more embodiments of the methods disclosed herein. In other embodiments, a plurality of method execution modules may be used to perform some aspects of methods herein.

It should be appreciated that computing system 500 is merely one example of a computing system, and that computing system 500 may have more or fewer components than shown, may combine additional components not depicted in the example embodiment of FIG. 5, and/or computing system 500 may have a different configuration or arrangement of the components depicted in FIG. 5. The various components shown in FIG. 5 may be implemented in hardware, software, or a combination of both hardware and software, including one or more signal processing and/or application specific integrated circuits.

Further, the steps in the processing methods described herein may be implemented by running one or more functional modules in information processing apparatus such as general-purpose processors or application specific chips, such as ASICs, FPGAs, PLDs, or other appropriate devices. These modules, combinations of these modules, and/or their combination with general hardware are included within the scope of the present disclosure.

Computational interpretations, models, and/or other interpretation aids may be refined in an iterative fashion; this concept is applicable to the methods discussed herein. This may include use of feedback loops executed on an algorithmic basis, such as at a computing device (e.g., computing system 500, FIG. 5), and/or through manual control by a user who may make determinations regarding whether a given step, action, template, model, or set of curves has become sufficiently accurate for the evaluation of the subsurface three-dimensional geologic formation under consideration.

The foregoing description, for purpose of explanation, has been described with reference to specific embodiments. However, the illustrative discussions above are not intended to be exhaustive or limiting to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to best explain the principles of the disclosure and its practical applications, to thereby enable others skilled in the art to best utilize the disclosed embodiments and various embodiments with various modifications as are suited to the particular use contemplated.

What is claimed is:

1. A method for automating analysis of a plurality of wells, the method comprising:
receiving input data comprising a database related to the plurality of wells;
receiving a submission related to the plurality of wells at an autonomous agent;
performing an automated workflow for the analysis of one or more wells of the plurality of wells based on the submission using the autonomous agent;
generating an output to the submission based on the automated workflow using a writer agent of the autonomous agent; and
displaying the output from the autonomous agent.

2. The method of claim 1, wherein the autonomous agent comprises one or more machine-learning (ML) models, wherein each ML model of the one or more ML models comprises a respective configuration file.

3. The method of claim 2, wherein the respective configuration file defines one or more parameters for operating each ML model of the one or more ML models.

4. The method of claim 3, wherein performing the automated workflow comprises:
selecting a first dataset of the database based on the submission using a data expert agent of the autonomous agent; and
performing a quality control workflow on the first dataset using the data expert agent based on the submission, the input data, or a combination thereof.

5. The method of claim 4, wherein performing the automated workflow further comprises generating a first set of predictions using a fast interpreter agent of the autonomous agent and at least one ML model of the one or more ML models and based on the first dataset, the submission, the input data, or a combination thereof.

6. The method of claim 5, wherein performing the automated workflow further comprises fine-tuning the at least one ML model using a refined interpreter agent of the autonomous agent to provide at least one fine-tuned ML model.

7. The method of claim 6, wherein the refined interpreter agent fine-tunes the at least one ML model based on the first set of predictions from the fast interpreter agent, the input data, the submission, or a combination thereof.

8. The method of claim 6, wherein fine-tuning the at least one ML model comprises modifying the respective configuration file of the at least one ML model using the refined interpreter agent to produce the at least one fine-tuned ML model comprising a modified configuration file.

9. The method of claim 8, wherein performing the automated workflow further comprises verifying a quality of the first set of predictions using a reviewer agent of the autonomous agent based on the input data, the one or more ML models, the at least one fine-tuned ML model, or a combination thereof.

10. The method of claim 1, further comprising performing an action in response to displaying the output, wherein the action comprises generating or transmitting a signal that recommends, instructs, or causes a physical action to occur, wherein the physical action comprises one or more of optimizing a trajectory of a wellbore drilling operation, conducting drilling operations, conducting an exploratory operation, utilizing a single-upscaled permeability model in a simulation model, designing a production strategy, designing a hydraulic fracturing strategy, conducting risk assessments, or any combination thereof.

11. A computing system, comprising:
one or more processors; and
a memory system comprising one or more non-transitory computer-readable media storing instructions that, when executed by at least one of the one or more processors, cause the computing system to perform operations for automating analysis of a plurality of wells, the operations comprising:
receiving input data comprising a database related to the plurality of wells;
receiving a submission related to the plurality of wells at an autonomous agent;
performing an automated workflow for the analysis of one or more wells of the plurality of wells based on the submission using the autonomous agent;
generating an output to the submission based on the automated workflow using a writer agent of the autonomous agent; and
displaying the output from the autonomous agent.

12. The computing system of claim 11, wherein:
the submission comprises a user query, a user request, or a combination thereof; and
the autonomous agent comprises one or more machine-learning (ML) models, wherein each ML model of the one or more ML models comprises a respective configuration file, and wherein the respective configuration file defines one or more parameters for operating each ML model of the one or more ML models.

13. The computing system of claim 12, wherein performing the automated workflow comprises:
identifying the user query, the user request, or a combination thereof of the submission using a planner agent of the autonomous agent;
selecting a first dataset of the database based on the submission using a data expert agent of the autonomous agent;
performing a quality control workflow on the first dataset using the data expert agent based on the submission, the input data, or a combination thereof;
generating a first set of predictions using a fast interpreter agent of the autonomous agent and at least one ML model of the one or more ML models and based on the first dataset, the submission, the input data, or a combination thereof; and
fine-tuning the at least one ML model using a refined interpreter agent of the autonomous agent to provide at least one fine-tuned ML model, wherein the refined interpreter agent fine-tunes the at least one ML model based on the first set of predictions from the fast interpreter agent, the input data, the submission, or a combination thereof.

14. The computing system of claim 13, wherein:
fine-tuning the at least one ML model comprises modifying the respective configuration file of the at least one ML model using the refined interpreter agent to produce the at least one fine-tuned ML model comprising a modified configuration file; and
performing the automated workflow further comprises verifying a quality of the first set of predictions using a reviewer agent of the autonomous agent based on the input data, the one or more ML models, the at least one fine-tuned ML model, or a combination thereof, wherein verifying the quality of the first set of predictions comprises performing an error analysis of the first set of predictions based on the input data, the submission, the one or more ML models, the at least one fine-tuned ML model, or a combination thereof.

15. The computing system of claim 14, further comprising further fine-tuning the at least one fined-tuned model using the refined-interpreter agent and based on the error analysis.

16. A non-transitory computer-readable medium storing instructions that, when executed by one or more processors of a computing system, cause the computing system to perform operations for automating analysis of a plurality of wells, the operations comprising:
receiving input data comprising a database related to the plurality of wells;
receiving a submission related to the plurality of wells at an autonomous agent;
performing an automated workflow for the analysis of one or more wells of the plurality of wells based on the submission using the autonomous agent;
generating an output to the submission based on the automated workflow using a writer agent of the autonomous agent; and
displaying the output from the autonomous agent.

17. The non-transitory computer-readable medium of claim 16, wherein:
the submission comprises a user query, a user request, or a combination thereof; and
the autonomous agent comprises one or more machine-learning (ML) models, wherein each ML model of the one or more ML models comprises a respective configuration file, and wherein the respective configuration file defines one or more parameters for operating each ML model of the one or more ML models.

18. The non-transitory computer-readable medium of claim 17, wherein performing the automated workflow comprises:
identifying the user query, the user request, or a combination thereof of the submission using a planner agent of the autonomous agent to provide an identified user query, an identified user request, or a combination thereof, respectively;
selecting a first dataset of the database based on the submission using a data expert agent of the autonomous agent, wherein the data expert agent selects the first dataset based on the identified user query, the identified user request, or a combination thereof;
performing a quality control workflow on the first dataset using the data expert agent based on the submission, the input data, or a combination thereof;
generating a first set of predictions using a fast interpreter agent of the autonomous agent and at least one ML model of the one or more ML models and based on the first dataset, the submission, the input data, or a combination thereof; and
fine-tuning the at least one ML model using a refined interpreter agent of the autonomous agent to provide at least one fine-tuned ML model, wherein the refined interpreter agent fine-tunes the at least one ML model based on the first set of predictions from the fast interpreter agent, the input data, the submission, or a combination thereof, wherein fine-tuning the at least one ML model comprises modifying the respective configuration file of the at least one ML model using the refined interpreter agent to produce the at least one fine-tuned ML model comprising a modified configuration file.

19. The non-transitory computer-readable medium of claim 18, wherein performing the automated workflow further comprises:
verifying a quality of the first set of predictions using a reviewer agent of the autonomous agent based on the input data, the one or more ML models, the at least one fine-tuned ML model, or a combination thereof, wherein verifying the quality of the first set of predictions comprises performing an error analysis of the first set of predictions based on the input data, the submission, the one or more ML models, the at least one fine-tuned ML model, or a combination thereof; and
further fine-tuning the at least one fined-tuned model using the refined-interpreter agent and based on the error analysis, wherein further fine-turning the at least one fine-tuned ML model comprises modifying the modified configuration file of the at least one fine-tuned ML model based on the error analysis.

20. The non-transitory computer-readable medium of claim 18, wherein performing the automated workflow further comprises:
selecting a second dataset of the database using the data expert agent and based on the first set of predictions from the fast interpreter agent, the first dataset, the submission, the input data, or a combination thereof; and
generating a second set of predictions using the fast interpreter agent and based on the second dataset, the submission, the one or more ML models, the at least one fine-tuned ML model, the input data, or a combination thereof,
wherein the refined interpreter agent fine-tunes the at least one ML model based on the first set of predictions and the second set of predictions.
